(19) United States
(12) Patent Application Publication
(10) Pub. No.: US 2010/0031121 A1
(43) Pub. Date: Feb. 4, 2010

(54) METHOD AND SYSTEM AGAINST BURST LOSS IN A DVB-H TRANSMISSION SYSTEM

(75) Inventors: Luc Ottavj, Valbonne (FR); Antoine Clerget, Mougins (FR)

Correspondence Address: BLAKELY SOKOLOFF TAYLOR & ZAFMAN LLP, 1279 OAKMEAD PARKWAY, SUNNYVALE, CA, 94085-4040, US

(73) Assignee: UDCAST, Valbonne (FR)

(21) Appl. No.: 12/524,159

(22) PCT Filed: Jan. 23, 2008
(86) PCT No.: PCT/EP2008/050771

§ 371 Date: Jul. 22, 2009

(30) Foreign Application Priority Data
Jan. 23, 2007 (FR) 0752829
Apr. 4, 2007 (FR) 0754285

(51) Int. Cl. H03M 13/05; G06F 11/10

(52) U.S. Cl. 714/762; 714/E11.032

(57) ABSTRACT

According to a first aspect, the invention relates to a method for protection against errors in a transmission system in which a data flow includes a plurality of time-divided base flows to be transmitted as bursts, characterised in that it comprises, for one base flow, calculating a direct inter-burst error correction, and associating the calculated correction with bursts of the flow in order to provide a protection against the total or partial loss of one or more bursts of the flow.

The field of the invention is that of communications systems, and more specifically that of communications systems for transmitting multimedia contents to portable terminals by means of digital radio broadcasting networks notably via a satellite link.

The DVB-H standard is an example of a Hertzian digital radio broadcasting standard for transmitting contents to portable terminals.

According to this standard, an IP stream of data comprises a plurality of elementary streams, each cut-up in time in order to be transmitted as bursts. Direct error correction FEC (Forward Error Correction) may be applied in order to provide a protection against loss of data within a burst.

The implementation of this correction (to which reference will be made subsequently under the name of ‘intra-burst FEC’) is described in document ETSI EN 301 192: “Digital Video Broadcasting (DVB); DVB specification for data broadcasting”, in particular in paragraph 9: “Time slicing and MPE-FEC”.

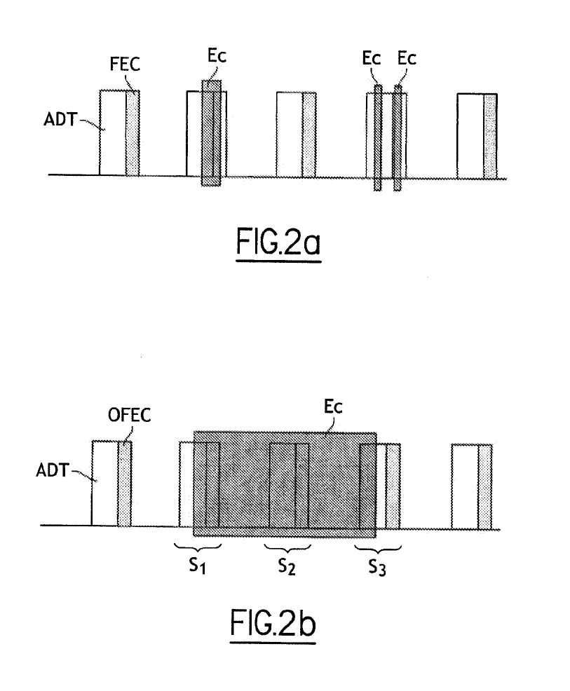

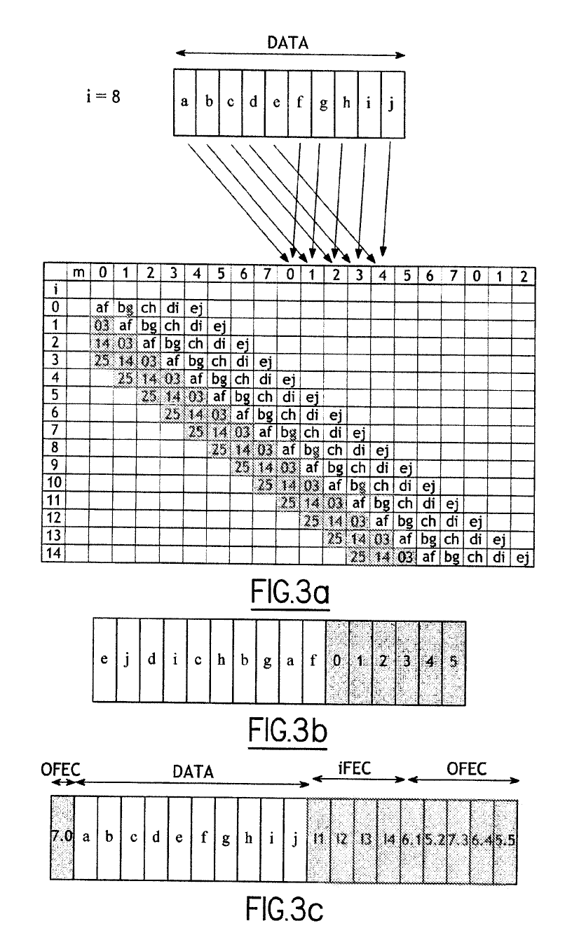

A description of this intra-burst error correction mechanism will also be found in the introductory part of the application PCT WO 2006/123231, in connection with FIGS. 2 and 3 of this application.

The DVB-H standard has the drawback of not being adapted to situations capable of having long interruptions or extinctions during reception. An example of such a situation is that where a terminal receiving a signal from a satellite is put onboard a vehicle and passes under a curtain of trees occulting the satellite for several seconds, or even several tens of seconds. Another example is that of a terminal moving in a mini-tunnel not equipped with any repeater (of the Gap Filler type) and which consequently will not be able to receive for a few seconds the signal emitted by the closest transmitter.

Now, the intra-burst FEC error correction proposed in the standard is not adapted to the correction of losses related to these long interruptions/extinctions. Calculated on the basis of data inside a burst, the intra-burst FEC correction only actually allows correction of losses inside a burst for which the duration is usually of the order of a fraction of a second (typically 100-200 milliseconds).

There is therefore a need for a technique allowing the standard DVB-H to be adapted to links capable of having long interruptions/extinctions, a particular a satellite link. This technique should notably allow loss data to be recovered during these long periods of interruptions/extinctions.

The goal of the invention is to meet this need, and proposes for this purpose and according to a first aspect, a method for protection against errors in a transmission system in which a stream of data comprises a plurality of time-sliced elementary streams in order to be transmitted as bursts, characterized in that it applies:

upon emitting each burst of an elementary stream, an inter-burst error correction calculation consisting in a forward error correction processing operation applied to interlaced data of a plurality of bursts of the elementary stream,

and a dispersion of the correction calculated over a plurality of bursts of the elementary stream, so as to associate with each burst of the elementary stream, data relating to the inter-burst correction.

Certain preferred, but non-limiting aspects of this method are the following:
the data of a burst are transmitted without any delay, accompanied by additional data relating to correction information which has been associated with this burst;
the emission of the burst is delayed, by delaying the emission of the data of a burst in order to transmit said data in a subsequent burst, or by delaying the emission of additional data relating to correction information which has been associated with this burst in order to transmit said additional data in a subsequent burst;
the data on a burst are transmitted as such in burst protected by the inter-burst forward error correction;
the inter-burst forward error correction is calculated on a sliding window of a plurality of interlaced B+S bursts;
the forward error correction processing operation applies a calculation of Reed-Solomon error correcting codes;
the calculated correction is dispersed over a plurality S of bursts of the elementary stream, so as to form a frame, a so-called MPE-OFEC frame for each burst;
an MPE-OFEC frame is encapsulated in sections, said sections comprising sections so-called MPE sections relating to the data of the burst and sections, so-called MPE-OFEC sections relating to the inter-burst correction;
the method also includes the introduction into each MPE-OFEC section of a header having information such that a receiver of the elementary stream is aware of the parameters for applying the inter-burst correction;
it also applies a protection against loss of data within a burst, said protection being provided by calculating an intra-burst forward error correction;
the interlacing consists of interlacing each burst of a plurality of B+S bursts of the elementary stream in Application Data Tables of a plurality B of matrices taken from a B+S plurality of matrices of the MPE-FEC type;
the forward error calculation applied to the interlaced bursts consists of calculating a Data Table RS for each of the matrices of the MPE-FEC type, with one calculated matrix per emitted burst;
the dispersion of the calculated correction consists of transmitting inter-burst FEC columns in a burst, said columns being selected from the Fo columns of a B+S plurality of said Data Tables RS;
the header information comprise the indications of the number (B) of bursts which are interlaced in order to calculate the inter-burst correction, as well as the indication of the number S of bursts on which the calculated inter-burst correction is dispersed;
upon receiving sections of an MPE-OFEC frame, the MPE sections are interlaced in the Application Data Tables of a B+S plurality of matrices of the MPE-FEC type, and the MPE-OFEC sections are placed in the Data Tables RS of said matrices of the MPE-FEC type, and in that, in the case of total or partial loss of a burst, the MPE sections of said lost burst are reconstructed from the data of the Data Tables RS in which the MPE-OFEC sections have been placed;
the transmission system is a DVB-H compatible system.

According to a second aspect, the invention also relates to a device comprising software and/or hardware means configured for applying the method according to the first aspect of the invention.

Other aspects, objects and advantages of the present invention will become better apparent upon reading the following detailed description of preferred embodiments thereof, given as a non-limiting example and made with reference to the appended drawings, wherein:

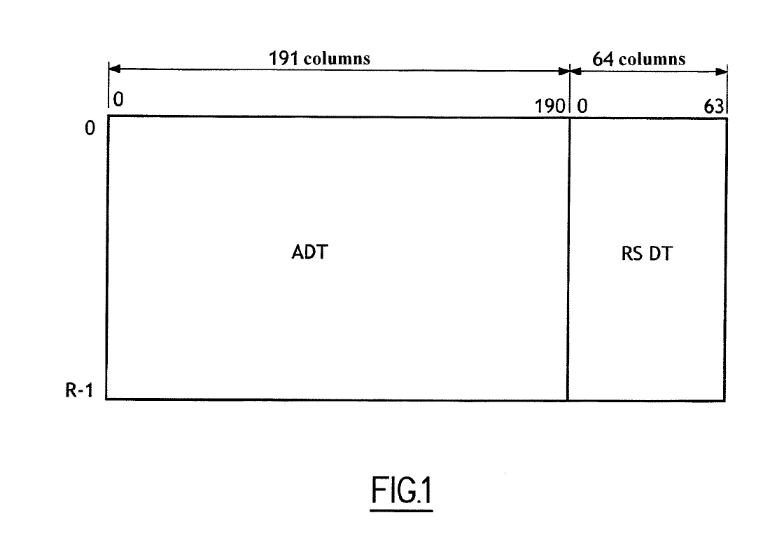

FIG. 1 illustrates an MPE-FEC frame according to the DVB-H standard;

FIGS. 2a and 2b illustrate the error correction by means of the intra-burst FEC according to the standard and by the inter-burst FEC proposed by the invention, respectively;

FIGS. 3a-3c illustrate the coding of a burst for associating therewith the inter-burst FEC error correction;

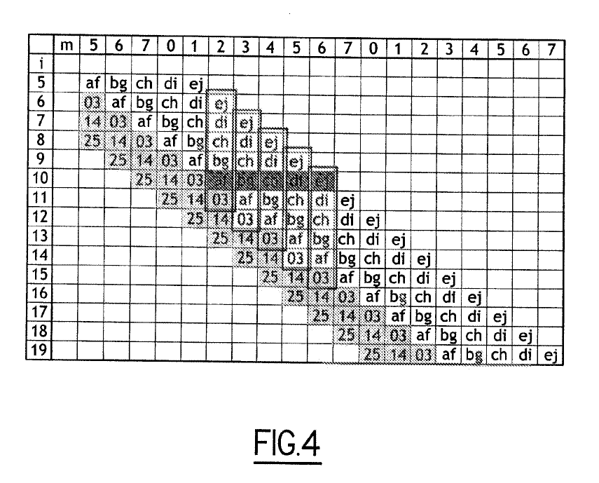

FIG. 4 illustrates the reconstruction of a burst completely lost by means of the inter-burst FEC error correction;

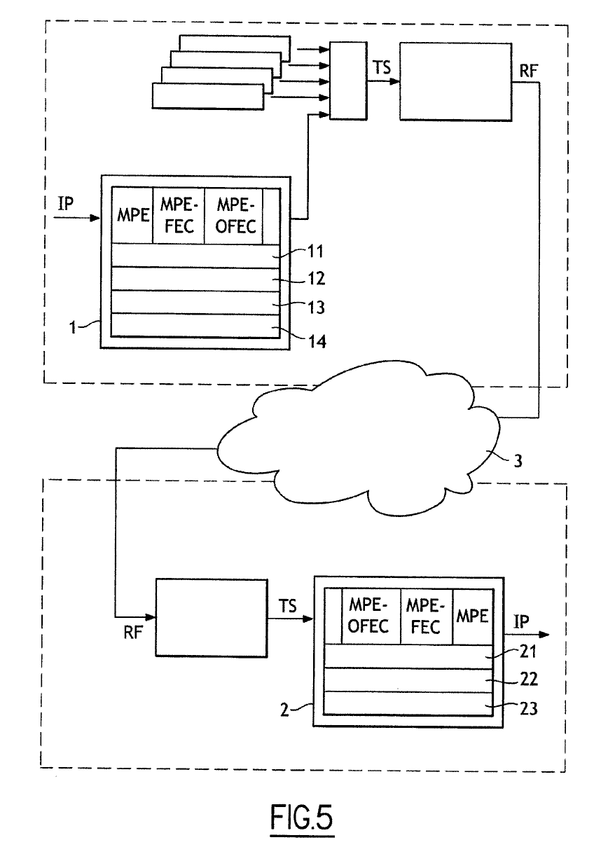

FIG. 5 illustrates a possible embodiment of a device according to the second aspect of the invention.

The invention has the setting of a transmission system in which a stream of data comprises a plurality of time-sliced elementary streams (ES, Elementary Streams) so as to be transmitted as bursts.

A preferential but non-limiting example of such a system is a system compatible with the DVB-H standard.

The invention proposes a mechanism for protection against losses due to long interruptions/extinctions of the transmission at the receiver. As such, the invention is particularly suitable, without however being limited thereto, for a transmission via a satellite link.

According to a first aspect, the invention proposes an error protection method in a transmission system in which a stream of data comprises a plurality of time-sliced elementary streams ES in order to be transmitted as bursts, said method applying a protection against total or partial loss of one or more bursts of a time-sliced elementary stream of data ES.

The protection is more specifically provided by performing an inter-burst forward error correction calculation, i.e. a direct correction calculation taking into account several bursts of an elementary stream ES.

Inter-burst FEC correction is associated with bursts of the stream for transmission towards the receiver, so that one or more bursts of a same elementary stream which would have been severely or totally degraded during transmission (i.e. received with residual errors, not corrected by the intra-burst FEC, or further not totally received at the receiver; typically a portable terminal in a mobility situation) may be entirely reconstructed by means of the inter-burst FEC correction.

The correction according to the invention thus allows extinction of the protection of the bursts to significant degradations or to complete losses of bursts, there where this protection was previously limited to moderate losses within the bursts by applying the intra-burst FEC correction of the standard.

With reference to FIG. 1, the calculation of the ‘intra-burst FEC’ correction recommended by the DVB-H standard is briefly recalled.

As illustrated in FIG. 1, a MPE-FEC frame is made up as a matrix of bytes comprising 255 columns and an adaptable number of lines (R, with a maximum of 1024).

The first 191 columns of this frame form the Application Data Table (ADT), acronym of Application Data Table), the last 64 form the Reed Solomon Data Table (RSDT, acronym of Reed Solomon Data Table). The ADT and RSDT tables form together an MPE-FEC matrix.

The datagrams of a burst are vertically grouped in the first C columns (C<191) and R lines in order to form the Application Data Table (ADT).

A Reed Solomon error correcting code having as parameters (255, 191, 64) and 8 bit symbols is calculated for each line of the MPE-FEC matrix. This leads to the calculation for each line of 191 bytes of data, a parity over 64 bytes. These parity bytes are stored in the lines of the RSDT table.

The data containing in the ADT are transmitted by columns into MPE sections (Multi Protocol Encapsulation) with one IP datagram per MPE section. A field of the MPE header indicates the position in bytes of the beginning of the datagram in the MPE-FEC matrix. Also, the MPE sections of a burst are numbered, this number as well as the number of the last section of the burst being indicated in each MPE frame.

Moreover, the MPE mechanism is provided with a CRC code allowing the receiver to discard as a whole an incomplete or erroneous section. This information will allow the receiver to properly place the IP datagrams received in the ADT of the receiver, and to localize the portions of the ADT to be reconstructed in the case of loss or error on the one hand and, to reinsert without transmitting them zeros in the right columns of the ADT when the number C of columns is less than 191, on the other hand.

The data contained in the RSDT table are transmitted in columns in MPE-FEC sections with one column per section, these MPE-FEC sections having a format close to MPE but of a different type.

The MPE-FEC sections of one burst are numbered, this number as well as the number of the last section being mentioned in each MPE-FEC frame. These sections are themselves also provided with a CRC.

This information will allow the receiver to properly place the FEC columns received in the RSDT table associated with the burst.

This correction, designated here by the term of intra-burst FEC correction, allows recovery of up to 64 lost columns on the 255 columns of the MPE-FEC matrix.

The effectiveness of this correction may be reduced by only transmitting part of the columns of the RSDT table (punching operation). This effectiveness may on the contrary be increased by not completely filling the table ADT, and by inserting in its last right columns non-transmitted zeros.

These mechanisms may also be used for providing constant effectiveness in a context where the size of the burst varies over time. This is achieved by providing for each burst a constant ratio between the number of non-zero columns of the ADT table and the number of effectively transmitted columns of the RSDT table.

It is therefore understood that the intra-burst FEC correction allows recovery of lost data within a burst.

This error correction is illustrated by FIG. 2a in which different bursts are illustrated, each consisting of ADT data and of FEC data of intra-burst FEC correction, as well as the correction of errors—schematized by a block Ec—capable of being achieved by means of the intra-burst FEC correction for losses inside a burst.

A preferential embodiment of the method according to the invention is descried hereafter.

The parameters useful to the method according to the invention are the following:
C: maximum number of columns of the ADT table of a burst
B: number of a bursts used for calculating the inter-burst error correction;
S: number of bursts used for dispersing the inter-burst error correction;
F₀: number of columns used for calculating the inter-burst error correction.

The steps of the preferential embodiment are described in the following, for a naïve case where: C=10, B=5, F₀=6 and S=3.

In order to perform the calculation of the inter-burst forward error correction, the data of a B+S plurality of bursts of an elementary stream ES are interlaced, and an FEC forward error correction processing operation is applied to the interlaced bursts.

As an initialization, B+S matrices (M(0), . . . , M(B+S−1), of size 191×R are formed and filled with zeros.

B+S matrices MF(0), . . . , MF(B+S−1) of size 64*R are also formed and initially filled with zeros. These matrices will allow reception of the (inter-burst) FEC associated with the data matrices MF(0), . . . , M(B+S−1).

In other words, B+S matrices of the MPE-FEC type are formed each having a matrix M(i) as an ADT table and a matrix MF(i) as a RSDT table.

It will be noted that there are as many sets of matrices (M, MF) as there are elementary streams being transmitted. It will in particular be noted that different parameters may be retained for the different elementary streams.

At the transmitter, the method applies the following steps for each burst of number I of a given elementary stream.

1. Step 1: sending of burst number i containing the data of this burst, optionally the intra-burst FEC and a portion of the inter-burst FEC calculated during the processing of the previous bursts of the same elementary stream.

2. Step 2: interlacing (with shifting of the ADT columns) of the emitted burst in the ADT tables (matrices M(m), m varying from 0 to B+S−1) of the MPE-FEC type matrices.

3. Step 3: calculation of FEC for the matrix M(m) (m=(i)[B+S])

In the following [X] refers to modulo X

4. i=i+1 and return to 1.

These different steps are schematized in FIGS. 3a-3c.

In FIG. 3a, the burst i=8 having the data a-j is illustrated. The data of this burst are interlaced as this is schematized by the arrows in FIG. 3a in the ADT tables (matrices M(m)) of B=5 matrices of type MPE-FEC.

It will be noted that in FIG. 3a, as in FIG. 4 which will be discussed subsequently, the data of the different matrices M(m) are illustrated by letters, while the calculated inter-burst FEC data for each of the matrices M(m) are illustrated by numbers.

FIG. 3b illustrates the MPE-FEC type matrix containing the data of matrix M(0) and the FEC data calculated for this matrix M(0) (these data being grouped in a matrix MF(0) as detailed hereafter).

FIG. 3c illustrates the emission of the burst i=8, further comprising the original data a-j DATA and the iFEC data of the intra-burst FEC, F₀=6 OFEC columns of inter-burst FEC (m.k designating the column k of matrix MF(m)).

The different steps applied upon emission are detailed hereafter.

Step 1: Transmission of the Burst
Burst No. i is prepared as a standard DVB-H burst. As such it may notably incorporate a standard intra-burst FEC.
The burst is sent without any delay:
   The DVB-H burst is sent as such, without any change relatively to the standard (by optionally incorporating the MPE(FEC sections relating to intra-burst FEC).
   MPE-OFEC sections relating to the inter-burst correction are added to burst No. i as follows. In this way a dispersion of the correction calculated on a plurality of bursts of elementary stream, is also achieved by forming in this way an MPE OFEC frame for each burst.
For k in zero, . . . F0-1, an Outer FEC packet OFEC (m,k) is calculated in the following way:
   m=((i−1)−k[S])[B] is defined
   OFEC(m,k)=column k of MF(m) is defined
   The Outer FEC packet OFEC(m,0) is sent at the beginning of the burst, the other Outer FEC packets are sent at the end of the burst.
      It is therefore understood that the data of the burst are transmitted as such in bursts protected by inter-burst FEC correction by sending Outer FEC packets at the beginning and at the end of the burst. For the columns of inter-burst FEC transmitted in a protected burst, columns are selected from the Fo columns of the B+S plurality of MF matrices.
   An MPE OFEC frame is thereby formed which may be encapsulated in sections: MPE sections relating to the data of the burst, optional MPE-FEC sections in the case of application of the intra-burst correction, and MPE-OFEC sections relating to the inter-burst correction.
The MPE-OFEC sections corresponding to a different table of the sections MPE and of the sections MPE-FEC. The values of i and of k are indicated inside the section.
A header is added to each MPE-OFEC section, this header having information such that a receiver of the elementary stream is aware of the parameters for applying the inter-burst FEC correction, notably parameters B and S.

The thereby sent i consists of Fo (F₀=6 in the example) columns of inter-burst FEC, of C data columns (C=10 in the example) and of P columns of intra-burst FEC (P=0 in the example).

The burst i=0 according to the example thus has the following format

### F7-0 0-a 0-b 0-c 0-d 0-e 0-f 0-g 0-h 0-i 0-j F-I F6-1 F5-2 F7-3 F6-4F5-5

Wherein:
F7-0 is the OFEC 0 column of RSDT MF(7)
0-a, 0-b, 0-c, 0-d . . . 0-j, are the first n non-zero columns of the ADT of burst 0, here n=10
F-I represents the P columns of the optional intra-burst FEC columns, which for sake of simplification, will no longer be mentioned subsequently.
F6-1, F5-2, F7-3, F6-4, FS−5 represent the OFEC columns 1, 2, 3, 4, 5 of the matrices RSDT MF(6), MF(5), MF(7), MF(6), MF(5)
   The bursts i=1, 2, 3, 4 and 5, as for them, have the following format:

Burst 1: F0-0-DATA -F7-1 F6-2 F0-3 F7-4 F6-5

Burst 2: F1-O -DATA -F0-1 F7-2 F1-3 F0-4 F7-5

Burst 3: F2-O-DATA -F1-1 F0-2 F2-3 F1-4 F0-5

Burst 4: F3-O-DATA -F2-1 F1-2 F3-3 F2-4 F1-5

Burst 5: F4-O-DATA -F3-1 F2-2 F4-3 F3-4 F2-5

Wherein DATA designates the columns of data.

It will be noted that the data of a burst are transmitted without any delay and that they contain DVBH standard information, accompanied by additional information (OFEC).

The result is that a terminal receiving such a stream, and not needing any OFEC information or not knowing how to process them, will have a behaviour and performances comparable with those which it would have add if it had received a normal DVB-H stream. These behaviour and performances are understood with regard to the subjects such as delay upon display or the time for changing channels (zapping).

It will moreover be noted that at their transmission, the OFEC information is dispersed over several bursts, thereby limiting the effects related to loss of transmission over long periods.

In the foregoing, a delayless transmission of data of a burst is considered. The burst of No. i actually contains the data of this first Data-i accompanied by additional OFEC-i data relating to OFEC inter-burst FEC information which is has been associated with this burst. Thus, Burst i=(Data-i, OFEC-i) was considered.

The invention is however not limited to such a transmission without any delay, the transmission of bursts may be delayed.

According to a first alternative embodiment, it is proposed to delay the transmission of data packets. Within the scope of this alternative, the OFEC-i packets are transmitted as described earlier in burst No.i, while the data packets Data-i of burst No.i are delayed and transmitted X burst latter, in burst No. X+i. Thus in this alternative it is proposed that burst No.i be transmitted according to:

Burst I=(Data-[i-X], OFEC-i).

It is understood that:
If X=0, this alternative is identical to what was described earlier;
If X<B+S, the OFEC inter-burst FEC is mixed with data;
If X=B+S, the OFEC inter-burst FEC is transmitted before the data.

By applying this alternative, a drawback lies in the fact that an end-to-end delay is added which extends over X bursts. An advantage lies in a reduction of the time required for correcting the losses, insofar that the OFEC inter-burst FEC is received with the original data.

According to a second alternative embodiment, it is proposed to delay the emission of the OFEC packets. Within the scope of this alternative, the data packets Data-i of burst number i are transmitted as described earlier, in burst number i, while the OFEC-i packets are delayed and transmitted Y bursts later, in burst number Y+i. Thus, it is proposed in this alternative that the burst number i be transmitted according to:

Burst I=(Data-i, OFEC-[i−Y]).

A drawback of this alternative lies in the increase in the time required for correcting the losses. This alternative however has the advantage of being particularly adapted to the correction of errors consecutive to very long extinctions upon reception.

Step 2: Interlacing in the Matrices M(m)

Interlacing of a B+S plurality of bursts of the elementary stream ES is achieved in the ADT tables of a B+S plurality of matrices of the MPE-FEC type, each burst being interlaced in a plurality B of matrices selected from a B+S plurality.

The columns of the ADT of burst i are interlaced in the B+S matrices M(0), . . . , M(B+S−1) in the following way.
Burst No.i occupies a matrix of size C*R (R being announced in the PSI/SI tables)
The C columns of data of burst No.i (containing R lines) are copied in the matrices M(m) in the following way.
   For j in 0, . . . C-1
      M=(i+(j[B]))[B+S] is defined
      The columns of the matrix M(m) are shifted:
         Col(1)->Col(0), Col(2)->Col(1), . . . , Col(C-1)->Col(C-2)
      The data column No.j is copied to column C-1 of the matrix M(m); if the burst contains less than C data columns, the copied data are filled with zeros.

In the example, for i=0, the 5+3=8 matrices M(0) . . . M(7) will be filled in the following way (the empty columns at the end of the matrix are not indicated for sake of legibility):
M(0)=0-a 0-f
M(1)=0-b 0-g
M(2)=0-c 0-h
M(3)=0-d 0-i
M(4)=0-e 0-j
M(5)=Void
M(6)=Void
M(7)=Void

For i=1 the contents of the matrices M(m) are the following:
M(0)=0-a 0-f
M(1)=0-b 0-g 1-a 1-f
M(2)=0-c 0-h 1-b 1-g
M(3)=0-d 0-i 1-c 1-h
M(4)=0-e 0-j 1-d 1-i
M(5)=1-e 1-j
M(6)=Void
M(7)=Void

It will be noted that the mechanism for calculating and transmitting the inter-burst FEC is sliding and therefore does not require strong synchronization between the transmitter and the receivers.

This mechanism in particular allows a gradual calculation of the inter-burst FEC: this calculation being further limited to an MPE-FEC frame at each burst.

This mechanism therefore differs from systems operating on blocks of B+S bursts, which would all require significant computation time for all the B+S bursts.

It will further be noted that the interlacing mechanism leads, when C is a multiple of B, to placing PB=C/B columns of a burst per matrix M(m) (PB=10/5=2 in the example) and that each matrix M(m) then contains in this case a fraction (1/B) of the B bursts among the last B+S bursts transmitted. However, the interlacing mechanism does not require having C as a multiple of B.

Step 3: Calculation of the inter-burst FEC on the matrix M(m): m=i[B+S]

The inter-burst FEC correction is calculated on a sliding window of B+S interlaced bursts.

The F₀ columns of FEC are calculated for the matrix M(i[B+S]) and stored in the matrix MF(i[B+S]). In other words, calculation of the RSDT table (matrix MF) was achieved for one of the MPE-FEC type matrices (the ADT table of which is the corresponding matrix M in which several bursts are interlaced).

At this stage, it will be noted that the calculation of FEC applied for each of the interlaced matrices M(i) may use, without this however being limiting (other error correcting codes may actually be applied), the same error correcting code as the one recommended in the DVB-H standard for calculating the intra-burst FEC (Reed Solomon Code 191, 255, 64 with 8 bit symbols).

It was also be noted that the calculation of FEC is an inter-burst calculation insofar that each FEC (matrix MF(i)) is calculated from data (matrices M(i)) comprising data of several interlaced bursts.

It will also be noted that the data of a burst are independent of the inter-burst FEC transmitted with this same burst, insofar that these data will be used for calculating the inter-burst FEC of the following B+S bursts.

The passage hereafter is a possible example of a structure for an MPE-OFEC sections. This example is given by comparison with the structure of an MPE-FEC section provided in the standard.

### MPE-FEC Section:

| | | |
|---|---|---|
| Syntax | Number of bits | Identifier |

MPE-FEC_section ( ) {

| | | |
|---|---|---|
| table_id | 8 | uimsbf |
| section_syntax_indicator | 1 | bslbf |
| private_indicator | 1 | bslbf |
| reserved | 2 | bslbf |
| section_length | 12 | uimsbf |
| padding_columns | 8 | uimsbf |
| reserved_for_future_use | 8 | bslbf |
| reserved | 2 | bslbf |
| reserved_for_future_use | 5 | bslbf |
| current_next_indicator | 1 | bslbf |
| section_number | 8 | uimsbf |
| last_section_number | 8 | uimsbf |
| real_time_parameters( ) | | |
| for( i=0; i<N; i++ ) { | | |

| | | |
|---|---|---|
| rs_data_byte | 8 | uimsbf |

| } | | |
|---|---|---|
| CRC_32 | 32 | uimsbf |

}

### MPE-OFE Section:

| | | |
|---|---|---|
| SYNTAX | Number of bits | Identifier |

MPE-OFEC_section {

| | | |
|---|---|---|
| table-id | 8 | uimsbf |
| section_syntax_indicator | 1 | bslbf |
| private_indicator | 1 | balbf |
| reserved | 2 | bslbf |
| section_length | 12 | uimsbf |
| interleaved bursts | 8 | uimsbf |
| outer-fec spread | 8 | uimsbf |
| burst number (cc) | 8 | uimsbf |
| reserved_for_future_use | 8 | bslbf |
| reserved | 2 | bslbf |
| reserved_for_future_use | 5 | bslbf |
| current_next_indicator | 1 | balbf |
| scction_number | 8 | uimsbf |
| last_section_number | 8 | uimsbf |
| real_time_parameters | | |
| for (i=0; i<N; i++) { | | |

| | | |
|---|---|---|
| rs_data_byte | 8 | uimsbf |

| } | | |
|---|---|---|
| CRC_32 | 32 | uimsbf |

}

The real-time parameters and their mapping in the MAC address field are:

| | | |
|---|---|---|
| SYNTAX | Number of bits | Identifier |

real_time_parameters {

| | | |
|---|---|---|
| delta_t | 12 | uimsbf |
| table_boundary | 1 | bslbf |
| frame_boundary | 1 | bslbf |
| address | 18 | uimsbf |

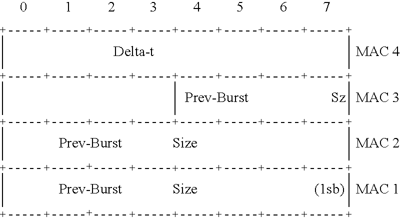

The semantics proposed here are the following:
Section_number:

This 8 bit field gives the number of the section. The ‘section_number’ of the first section bearing the data RS of an MPE-OFEC frame is 0x00. The ‘section_number’ is incremented by 1 with each additional section bearing the RS data of the relevant MPE-OFEC frame (this field thus bears the parameter k).
Last section-number:
   This field indicates the number of the last section which is used for bearing the RS data of the current MPE-OFEC frame (this field thus bears the parameter F₀).
Interleaved bursts:
   This field gives the number B of bursts which are interlaced for calculating the inter-burst FEC
Outer-fec spread:
   This field gives the number S of transmitted bursts on which the inter-burst FEC is dispersed.
Burst number:
   This field bears a burst number (as a continuous counter) varying between 0 and n−1, where N is the largest multiple of B less than 256 (this field thus bears the parameter i).
Prev-Burst Size:
   This 18 bit field bears the actual size (only table ADT) of the burst (i-k-1).

The reception of the sections of an MPE-OFEC frame is described hereafter as well as the applied correction mechanism in the case of total or partial loss of one or more bursts.

Upon receiving sections from an MPE-OFEC frame, the MPE sections are interlaced in the ADT tables (the RM matrices hereafter) of a B+S plurality of matrices of the MPE-FEC type, and the MPE-OFEC sections are placed in the RS Data Tables (RF matrices hereafter) of said matrices of the MPE-FEC type. In the case of total or partial loss of a burst, the MPE sections of a lost burst are reconstructed from the data of the RS Data Tables in which the MPE-OFEC sections were placed.

A possible mode of the method for the decoding is the following.
Initialization:

As an initialization, the decoder needs to know the parameters B and S. The parameter Fo does not have to be known beforehand.

The decoder allocates B+S matrices RM(0), . . . , RM(B+S−1), of size C×R, filled with zeros.

It also allocates B+S FEC matrices RF(0), . . . RF(B+S-1) in order to receive the FEC of the data matrices RM(0), . . . RM-B+S−1). These FEC matrices have a size of 64×R, and are filled with zeros.

The last number of the corrected burst Y, transmitted to the upper layer is initialized from the first number of received burst P: Y=P -1.
Step 1: Replace the received sections in the burst sequence
Upon receiving an MPE/MPE-FEC section, the decoder determines its first number:
Let ip/tp/dtp be the burst number, the reception time, and the delta-t field of the previous MPE-OFEC section received after this MPE section, respectively
Let in/tn/dtn be the burst number and the reception time and the delta-t field of the next MPE-OFEC section respectively
If (ip==in) burst_number=i=ip=in
Hence, the result may be based on the following
   IF tp+dtp<t and t+dt>tn THEN i=in
   ELSE IF tp+dtp>t AND t+dt<tn THEN i=ip
   ELSE IGNORE this MPE section for decoding the inter-burst FEC.
Step 2: Regenerate a complete sequence of (pseudo) bursts
   The sequence of received bursts is completed right up to the burst number being received, with pseudo-bursts representing the totally lost bursts, and the lost columns of the partly received bursts are marked as being missing.
   With the “Pre-Burst Size” field of the MPE-OFEC packets, the size of the preceding bursts may be known. This information is utilized in order to mark the data beyond the end of the burst as being not missing but having the value zero.
Step 3: Utilizing the intra-burst FEC
   The received intra-burst FEC of the bursts is utilized by exploiting the standard MPE-FEC mechanisms. The latter is of course not exploitable for the missing bursts pseudo-bursts).
      For each of the new bursts or received pseudo-burst:
Step 4: Place the inter-burst FEC in the RF matrices
   For all the sections of MPE-OFEC (received or which should have been received), of index (of “section_number”) k=0 . . . F₀-1:
m=((i-1)-k[S])[B+S]
The MPE-OFEC (pseudo-)packet is inserted in the matrix RF(m) in the k position
Step 5: Utilizing the inter-burst FEC
   For k=0, . . . S−1
      m=((i−1)−k[S])[B+S]
      Correct the losses present in the matrix RM(m) with the inter-burst FEC present in the matrix RF(m)
Step 6: Have the corrected burst move up to the upper layer
   If the burst Y+1 is complete have this burst move up to the upper layer. Then Y=Y+1.
      In this case (case A “ordered differed”) for which as long as a frame is being reconstructed and is always reconstructible, the subsequent bursts are blocked in order to put back the whole into the right order but in a differed way. The case B “immediate disorder” is also provided, for which the properly received bursts are moved up to the upper layer without any delay, only the datagrams obtained by reconstructing a burst arriving in the upper layer in a differed way and in disorder.
   Else, if Y=i-B-S, it will be no longer possible to correct the burst Y. Then Y=Y+1.
Step 7: Insertion of the data in the RM matrices
   for i=0, . . . C-1
m=(i+j[B])[B+S]
The columns of matrix RM(m) are left-shifted
The column i of the burst is inserted in the matrix RM(m) in column C-1

The reception of seven bursts of index i=9 to i=15, is described hereafter, with a loss of the integrality of the data of burst number 10 (i=10).

These steps are illustrated by the diagram of FIG. 4 on which the loss of the burst i=10 is considered, this diagram provides viewing of the matrices used for reconstructing the data a-j of this burst.

Thus, inter-burst FEC columns of the burst 11 (block 03 in the figure) are utilized for reconstructing the data columns af of the burst 10. Also, the inter-burst FEC columns of burst 12 are utilized for reconstructing the data column bg of the burst 10. And this, and so forth until utilization of the inter-burst FEC columns of the burst 15 for reconstructing the data columns ej of the burst 10.

As this is apparent in FIG. 4, it is therefore understood that the entirely lost data of burst 10 may be reconstructed with the inter-burst FEC columns associated with the bursts 11-15.

By placing oneself at the reception of the burst 11, the receiver having received without any error the frames 0-9 will more specifically carry out the following steps.

Step 1: Reception of the frame 11, known by its number in the MPE header of the received OFEC frames and detection of the loss of the frame 10, the last received frame being frame No. 9.

Step 2: A pseudo burst (i=10) is generated, all the data and FEC columns are marked as being missing (L):

Pseudo Burst 10: F1-0(L)−DATA(L)−F0-1(L) F7-2(L) F1-3(L) F0-4(L) F7-5(L)

Step 3: The intra-burst FEC cannot be calculated for the totally lost pseudo burst 10, it may be calculated for frame 11
For the pseudo burst 10

Step 4: this leads to marking the columns RF1-0 RF0-1 RF7-2 RF1-3 RF0-4 RF7-5 columns as missing

Step 5: This step is inapplicable for a totally lost burst

Step 6: This step is inapplicable for a totally lost burst

Step 7: the columns of the pseudo burst 10 are marked as missing (L-10) in the RM matrices:
RM(0)=4-e 4j 5-d 5-i 6-c 6-h 7-b 7-g 8-a 8-f
RM(1)=5-e 5-j 6-d 6-i 7-c 7-h 8-b 8-g 9-a 9-f
RM(2)=6-e 6-j 7-d 7-i 8-c 8-h 9-b 9-g L-10 L-10
RM(3)=3-a 3-f 7-e 7-j 8-d 8-i 9-c 9-h L-10 L-10
RM(4)=3-b 3-g 4-a 4-f 8-e 8j 9-d 9-i L-10 L-10
RM(5)=3-c 3-h 4-b 4-g 5-a 5-f 9-e 9-j L-10 L-10
RM(6)=3-d 3-i 4-c 4-h 5-b 5-g 6-a 6-f L-10 L-10
RM(7)=3-e 3-j 4-d 4-i 5-c 5-h 6-b 6-g 7-a 7-f
For burst 11
   This burst contains:

### F2-0 11-a 11-b 11-c 11-d 11-e 11-f 11-g 11-h 11-i 11-j F1-1 F0-2 F2-3 F1-4 F0-5

Step 4: The columns: F2-0 F1-1 F0-2 F2-3 F1-4 F0-5 of the matrices RF(2),RF(1),RF(0) are filled with values received in burst 11.

At this stage, the transmitted FEC have been calculated from the contents of matrices M indicated in the following:

F2-0 and F2-3 from M(2) containing (6-e:6,j:7-d:7-i:8-c:8-h:9-b:9-g:10-a:10-f:)
F1-1 and F1-4 from M(1) containing (5-e:5-j:6-d:6-i:7-c:7-h:8-b:8-g:9-a:9-f:)
F0-2 and F0-5 from M(0) containing (4-e:4-j:5-d:5-i:6-c:6-h:7-b:7-g:8-a:8-f:)

Step 5: By utilizing the matrices RM(2) RF(2) for k=0 and k=3 it is possible to find again the columns 10-a and 10-f of burst 10, indeed:

### RM(2)=6-e 6-j 7-d 7-i 8-c 8-h 9-b 9-g L-10 L-10 and

RF2-0 calculated from (6-e 6-j 7-d 7-i 8-c 8-h 9-b 9-g 10-a 10-f)
RF2-1 calculated from (0-c 0-h 1-b 1-g 2-a 2-f)
RF2-2 calculated from (0-c 0-h 1-b 1-g 2-a 2-f)
RF2-3 calculated from (6-e 6-j 7-d 7-i 8-c 8-h 9-b 9-g 10-a 10-f)
RF2-4 calculated from (0-c 0-h 1-b 1-g 2-a 2-f)
RF2-5 calculated from (0-c 0-h 1-b 1-g 2-a 2-f)

Step 6: The case A is described here (ordered and deferred restoration). In this case, no frame is moved up to the upper layer for i=11, 12, 13, 14. Indeed, reception of bursts of no. i=12, 13, 14, 15 will allow reconstruction of columns 10-b 10-g, 10-c 10-h, 10-d 10-i, 10-e and 10-j, respectively. Burst 10 will be completely reconstructed as soon as frame 15 is received and the different IP datagrams contained in its ADT are moved up to the upper layer, as well as the datagrams obtained by processing the bursts 12.13.14.15 and contained in the RM matrices.

Step 7: The data of burst 11 are interlaced in the RM matrices of the receiver which will contain:

### RM(0)=4-e 4-j 5-d 5-i 6-c 6-h 7-b 7-g 8-a 8-f

### RM(1)=5-e 5-j 6-d 6-i 7-c 7-h 8-b 8-g 9-a 9-f

### RM(2)=6-e 6-j 7-d 7-i 8-c 8-h 9-b 9-g L-10 L-10

### RM(3)=7-e 7-j 8-d 8-i 9-c 9-h L-10 L-10 11-a 11-f

### RM(4)=4-a 4-f 8-e 8-j 9-d 9-i L-10 L-10 11-b 11-g

### RM(5)=4-b 4-g 5-a 5-f 9-e 9j L-10 L-10 11-c 11-h

### RM(6)=4-c 4-h 5-b 5-g 6-a 6-f L-10 L-10 11-d 11-i

### RM(7)=4-d 4-i 5-c 5-h 6-b 6-g 7-a 7-f 11-e 11-j

It will have been understood that the method according to the first aspect of the invention provides an extension of the DVB-H standard, by proposing the application of an inter-burst FEC correction making possible the recovery of entire bursts.

This error correction is illustrated in FIG. 2b, given as a comparison with FIG. 2a, in which different bursts have been illustrated, each consisting of ADT data and inter-burst FEC correction OFEC data, as well as the correction of errors—schematized by a block Ec—capable of being achieved by means of the inter-burst FEC correction for the total or partial loss of one or more bursts. In FIG. 2b, the error correction Ec thus allows recovery of the partly lost data of bursts S1 and S3 and of the totally lost data of burst S2.

By comparison with FIG. 2a, it is understood that the inter-burst correction according to the invention allows the error correction to be extended to lost data during long periods of interruptions/extinctions.

This method further has the following advantages:
the proposed method is compatible with the existing standard, in that a DVB-H stack is capable of comprising the transport stream TS (acronym for Transport Stream) resulting from the application of the method according to the invention.
the proposed method retains the possibility of battery savings provided by DVB-H. Indeed the time dispersions performed on the data in order to calculate the inter-burst FEC and broadcast it, are exclusively accomplished on successive occurrences of the bursts of a given service and not on consecutive data in the TS (Transport Stream). The terminal may turn off its radio circuit between the occurrences of the bursts.
no delay is provided upon transmission, and the terminals receiving under good conditions do not have any additional delay in reception, they will retain short channel changing (zapping) times.
the terminals placed under bad receiving conditions have to wait for the arrival of the next bursts in order to correct a severely or totally erroneous burst.
   It should be noted that in this case, the terminal may either freeze the image and wait for the correction in order to resume the display there where it was interrupted (analogous to time-shifting), or preventively display at a slower rate (e.g. 20 images per second) upon the starting of a service for sufficient time in order to accumulate in its memory sufficient information for, this time, reconstructing a lost burst immediately.
the parameters of the proposed method may be adjusted for adapting to the desired characteristics
   the interdependency time range between the (B+S) bursts may be adjusted;
   the direct amount of error correction (i.e. its robustness to signal loss) may be adjusted;
   the parameters may be selected so as to adjust the maximum memory size in the receiving terminal;
   the inter-burst FEC may use the same error correcting code (Reed-Solomon (191,255)) and s=8 as the one used for the intra-burst FEC, and is in particular capable of reusing the hardware present in the DVB-H compatible receivers.
   for a same FEC level, the required computing power for inter-burst FEC is the same as that required for intra-burst FEC.
   the inter-burst FEC may act as a complement to the intra-burst FEC, or else as a total or partial replacement.
   the inter-burst FEC may correct complete bursts or portions of bursts.

The invention is of course not limited to the method described earlier, but extends to an electronic device comprising software and/or hardware means configured for applying this method, both upon transmission (to achieve inter-burst FEC coding) and upon reception (to achieve inter-burst FEC decoding and recovery of the partly or totally lost burst(s)).

A device 1 capable of applying the inter-burst FEC coding is schematically illustrated in FIG. 5. This device typically repeats the functions of an IP encapsulator receiving IP streams, slicing them in time, calculating the intra-burst FEC protection, encapsulating the IP packets and embedding them in the transport stream. It also includes means for calculating the inter-burst protection, applying means 11 for interlacing bursts of an elementary stream, means 12 for calculating FEC for interlaced bursts, means 13 for dispersing the thereby computed inter-burst FEC on bursts of the elementary stream in order to form an MPE-OFEC frame, and means 14 for encapsulating this frame in MPE-OFEC sections.

It will be noted that the device 1 for calculating the inter-burst FEC may also be integrated into devices of the DVB-H distribution chain (multiplexer, network adapter of the SFN chain, or in devices such as the iSplicer from Udcast, notably in the case when the device computes the inter-burst FEC and inserts it as an addition or replacement of the intra-burst FEC.

A device 2 is also schematically illustrated in FIG. 5, which is receiving a transport stream TS which has passed through the link comprising the network 3 and comprising in addition to the standard functions of a de-encapsulator (recovery of IP datagrams and correction against intra-burst losses from MPE and MPE-FEC sections), means for correction against the loss of one or more entire bursts, these means comprising means 21 for interlacing MPE-FEC frames, means 22 for applying the correction on interlaced frames in order to recover the lost burst(s), as well as means 23 for deinterlacing interlaced frames corrected against losses.

1. A method for protection against errors in a transmission system wherein a data stream comprises a plurality of time-sliced elementary streams (ES) in order to be transmitted as bursts, characterized in that it comprises:
upon transmission of each burst of an elementary stream, an inter-burst error correction calculation consisting in a forward error correction processing operation (FEC) applied to interlaced data of a plurality of bursts of the elementary stream,
and a dispersion of the correction calculated on a plurality of bursts of the elementary stream, so as to associate with each burst of the elementary stream, data relating to the inter-burst correction.

2. The method according to claim 1, wherein the data of a burst are transmitted without any delay, accompanied by additional data relating to correction information which has been associated with this burst.

3. The method according to claim 1, wherein the transmission of the bursts is delayed, by delaying transmission of the data of a burst in order to transmit said data in a subsequent burst, or by delaying the transmission of additional data relating to correction information which has been associated with this burst in order to transmit said additional data in a subsequent burst.

4. The method according to claim 1, wherein the data of a burst are transmitted as such in bursts protected by the inter-burst forward error correction.

5. The method according to any of the preceding claim 1, wherein the inter-burst forward error correction is calculated on a sliding window of a plurality of (B+S) interlaced bursts.

6. The method according to claim 5, wherein the forward error correction processing operation applies a calculation of Reed-Solomon error correcting codes.

7. The method according to claim 5, wherein the calculated correction is dispersed over a plurality (S) of bursts of the elementary stream, so as to form a so-called MPE-OFEC frame for each burst.

8. The method according to claim 7, wherein an MPE-OFEC frame is encapsulated in sections, said sections comprising sections, so-called MPE sections, relating to the data of the burst and sections, so-called MPE-OFEC sections, relating to the inter-burst correction.

9. The method according to claim 8, characterized in that is also includes the introduction into each MPE-OFEC section of a header having information such that a receiver of the elementary stream is aware of the parameters for applying the inter-burst correction.

10. The method according to claim 1, also comprising a protection against loss of data within a burst, said protection being provided by calculating an intra-burst forward error correction.

11. The method according to claim 1, wherein the interlacing consists in interlacing each burst of a (B+S) plurality of bursts of the elementary stream (ES) in Application Data Tables (ADT) of a plurality (B) of matrices taken from a (B+S) plurality of matrices of the MPE-FEC type.

12. The method according to claim 11, wherein the forward error calculation applied to the interlaced burst consists of calculating an RS Data Table (RSDT) of each of the matrices of the MPE-FEC type, with one calculated matrix per transmitted burst.

13. The method according to claim 12, wherein the data of a burst are transmitted as such in bursts protected by the inter-burst forward error correction the inter-burst forward error correction is calculated on a sliding window of a plurality of (B+S) interlaced bursts, the calculated correction is dispersed over a plurality (S) of bursts of the elementary stream, so as to form a so-called MPE-OFEC frame for each burst and wherein the dispersion of the calculated correction consists of transmitting inter-burst FEC columns in a burst, said columns being selected from the F₀ columns of a (B+S) plurality of said RS Data Tables (RSDT).

14. (canceled)

15. (canceled)

16. The method according to claim 1, wherein the transmission system is a DVB-H compatible system.

17. A device comprising software and/or hardware means configured for applying the method of claim 1.

18. The method according to claim 9, wherein the header information comprises the indication of the number (B) of bursts which are interlaced for calculating the inter-burst correction, as well as the indication of the number (S) of bursts on which the calculated inter-burst correction is dispersed.

19. The method according to claim 18, wherein upon reception of the sections of an MPE-OFEC frame, the MPE sections are interlaced in Application Data Tables (ADT) of a (B+S) plurality of matrices of the MPE-FEC type, and the MPE-OFEC sections are placed in the RS Data Tables of said matrices of the MPE-OFEC type, and in that, in the case of total or partial loss of a burst, the MPE sections of said lost burst are reconstructed from data of the RS Data Tables in which the MPE-OFEC sections have been placed.
